(19) United States
(12) Patent Application Publication
(10) Pub. No.: US 2005/0269583 A1
(43) Pub. Date: Dec. 8, 2005

(54) Gallium nitride-based semiconductor light-emitting device and method of fabricatiing the same

(75) Inventors: Dong Joon Kim, Seoul (KR); Je Won Kim, Suwon (KR); Sun Woon Kim, Seoul (KR); Kyu Han Lee, Suwon (KR); Jeong Tak Oh, Suwon (KR)

Correspondence Address: LOWE HAUPTMAN GILMAN AND BERNER, LLP, 1700 DIAGONAL ROAD, SUITE 300 /310, ALEXANDRIA, VA, 22314, US

(73) Assignee: SAMSUNG ELECTRO-MECHANICS CO., LTD., Suwon (KR)

(21) Appl. No.: 10/899,035

(22) Filed: Jul. 27, 2004

(30) Foreign Application Priority Data
Jun. 4, 2004 (KR) 2004-40771

(51) Int. Cl. H01L 33/00

(52) U.S. Cl. 257/94

(57) ABSTRACT

This invention pertains to a gallium nitride-based semiconductor light-emitting device, in which nano-sized, fine protrusions are formed on an upper surface of a p-type clad layer without a deterioration of crystallinity and electric conductivity to improve light extraction efficiency, and a method of fabricating the same. After a first conductive gallium nitride-based semiconductor layer and an active layer are grown on a substrate under typical growth conditions, a second conductive gallium nitride-based semiconductor layer is grown on a polarity conversion layer containing a MgN-based single crystal and formed on the active layer, so that a polarity of the second conductive gallium nitride-based semiconductor layer is converted into an N polarity, thereby roughing a surface thereof.

### BACKGROUND OF THE INVENTION

1. Field of the Invention

The present invention relates, in general, to a gallium nitride-based semiconductor light-emitting device for opto-electronic devices and, more particularly, to a gallium nitride-based semiconductor light-emitting device, in which nano-sized, fine protrusions are formed on an upper surface of a p-type clad layer without a deterioration of crystallinity and electric conductivity to improve light extraction efficiency, and a method of fabricating the same.

2. Description of the Prior Art

Generally, a gallium nitride-based semiconductor light-emitting device is fabricated by forming a semiconductor layer, which emits light with a blue or green wavelength range, using a gallium nitride-based substance, particularly, a semiconductor substance with a compositional formula of AlₓIn_{y}Ga_{(1-x-y)}N (wherein, 0≦x≦1, 0≦y≦1, and 0≦x+1≦1), and has a structure in which a first conductive gallium nitride-based (hereinafter, referred to as “GaN”) semiconductor layer 12, an active layer 13, and a second conductive GaN semiconductor layer 14 are sequentially grown on a substrate 11 made of different materials, such as sapphire or SiC, as shown in FIG. 1.

Efforts for developing a light-emitting device using such gallium nitrides (GaN) are progressing in a direction of replacing incandescent lights, fluorescent lights, halogen lights, neon lights and the like, used as a typical light source, with the light-emitting device with improved brightness. In 1994, commercialization of a blue light-emitting device was achieved using AlGaInN, but it had very low internal quantum efficiency (IQE) because of poor crystallinity of a GaN semiconductor layer. The reason why the crystallinity was poor is that a substrate material corresponding to a lattice constant of AlGaInN was not adopted, but in recent years, advances in thin film growth technologies have resulted in the significant reduction of a crystal defect density in the thin film as a standard of the crystallinity, even though the substrate material being in accord with the lattice constant has not yet been found.

With respect to this, recently, studies have been conducted to maximize light extraction efficiency so as to improve brightness of gallium nitride-based semiconductor light-emitting devices.

Generally, a refractive index of a semiconductor material applied to the gallium nitride-based semiconductor light-emitting device is higher than that of air or a package (PKG) material. For example, the refractive index of a gallium nitride-based material is 2.4 or higher, which is higher than that (1.5 or lower) of a silicone-based or epoxy-based material frequently used as the package material.

Accordingly, since a portion of light emitted from the semiconductor layer is totally reflected by an interface between a package and the semiconductor layer, it cannot be radiated from the package. In order to reduce such a total reflection, it is necessary to form nano-sized, fine protrusions on an upper surface of the second conductive GaN semiconductor layer 14 to adjust an incidence angle of light to a critical angle or less, from which light is finally radiated, thereby a total reflectivity is reduced, resulting in improved light extraction efficiency.

In this respect, there is a method of roughing an upper surface of a second GaN semiconductor layer 14, in which a first GaN semiconductor layer 12 and an active layer 13 are sequentially grown on a substrate 11 and the second GaN semiconductor layer 14 is then grown on the resulting structure at a low temperature of about 400-1000° C.

However, the method is problematic in that when the second GaN semiconductor layer 14 is directly grown at such low temperature, a portion of recesses of a finely rugged structure, including protrusions and the recesses, may reach an inside of the active layer 13, and thus, crystallinity of the active layer 13 is reduced to decrease luminous efficiency, and in the case of an excessive flow of electricity, the excess electricity concentrated on the recesses may flow below the active layer 13, thus causing significant problems or risk of ESD (electrostatic discharge). To avoid the above problems, after the active layer 13 is grown, a portion of a p-clad layer having a flat surface and the remaining portion of the p-clad layer may be grown at high and low temperatures, respectively, but this procedure is disadvantageous in that it is complicated and a surface roughness may be reduced.

According to another method, after a first GaN semiconductor layer 12 and an active layer 13 are grown, a second GaN semiconductor layer 14 is grown in an amorphous state at low temperatures and then heat treated to increase a roughness of an upper surface of the second GaN semiconductor layer 14. However, typically, the physical properties, such as crystallinity and electric conductivity, of the second GaN semiconductor layer 14 can be desirably gained when the second GaN semiconductor layer 14 is grown at a high temperature of 1000° C. or higher, and thus, the crystallinity may be reduced in this method.

### SUMMARY OF THE INVENTION

Therefore, the present invention has been made keeping in mind the above disadvantages occurring in the prior arts, and an object of the present invention is to provide a gallium nitride-based semiconductor light-emitting device, in which nano-sized, fine protrusions are formed on an upper surface of a p-type clad layer without a reduction of crystallinity and electric conductivity to improve light extraction efficiency, and a method of fabricating the same.

The above objects can be accomplished by providing a gallium nitride-based semiconductor light-emitting device, which includes a substrate, and a first conductive gallium nitride-based semiconductor layer formed on the substrate. An active layer is grown on the first conductive gallium nitride-based semiconductor layer to have a Ga polarity. A polarity conversion layer, containing an MgN-based single crystal, is formed on the active layer. Additionally, a second conductive gallium nitride-based semiconductor layer is grown on the polarity conversion layer to have an N polarity.

In the gallium nitride-based semiconductor light-emitting device of the present invention, the polarity conversion layer is made of a material satisfying a compositional formula of (AlₓGa_{y}In_{z})Mg_{3-(x+y+z)}N₂, provided that 0≦x,y,z≦1and 0<x+y+z<3, and may be formed according to an MBE process or an MOCVD process. Furthermore, it is preferable that the polarity conversion layer is formed in a thickness of 500 Å or less so as not to reduce light transmittance therethrough.

As well, the above objects can be accomplished by providing a method of fabricating a gallium nitride-based semiconductor light-emitting device, which includes forming a first conductive gallium nitride-based semiconductor layer on a substrate; growing an active layer with a multi quantum well structure so as to have a Ga polarity on the first conductive gallium nitride-based semiconductor layer; forming a polarity conversion layer on the active layer; and growing a second conductive gallium nitride-based semiconductor layer so as to have an N polarity on the polarity conversion layer.

In this respect, as described above, the polarity conversion layer is made of the material satisfying a compositional formula of (AlₓGa_{y}In_{z})Mg_{3-(x+y+z)}N₂, provided that 0≦x,y,z≦1and 0<x+y+z<3, may be formed according to the MBE or MOCVD processes, and it is preferable that the polarity conversion layer is formed in the thickness of 500 Å or less.

The method of fabricating a gallium nitride-based semiconductor light-emitting device according to the present invention may also include etching an upper surface of the second conductive gallium nitride-based semiconductor layer according to a wet etching process, thereby further increasing a surface roughness of the second conductive gallium nitride-based semiconductor layer. At this time, an etching solution may be selected from the group consisting of a molten potassium hydroxide (KOH) solution, a phosphoric acid solution, a sulfuric acid solution, and a mixed solution of phosphoric acid and sulfuric acid.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a sectional view of a conventional gallium nitride-based semiconductor light-emitting device;

FIG. 2 is a sectional view of a gallium nitride-based semiconductor light-emitting device according to the present invention;

FIG. 3 is a SEM (scanning electron microscope) picture illustrating a surface of a GaN thin film grown to have a Ga polarity;

FIG. 4 is a SEM picture illustrating a surface of a GaN thin film grown to have an N polarity according to the present invention;

FIG. 5 is a SEM picture illustrating a surface of a GaN thin film etched after it is grown to have an N polarity according to the present invention; and

FIG. 6 is a flow chart illustrating the fabrication of the gallium nitride-based semiconductor light-emitting device according to the present invention.

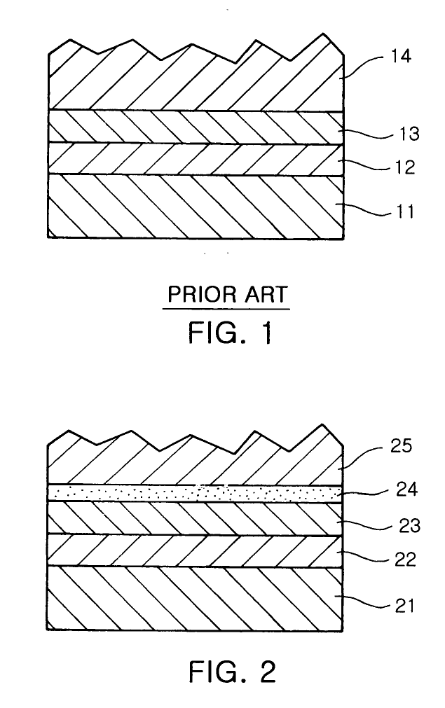

### DETAILED DESCRIPTION OF THE INVENTION

Hereinafter, a detailed description will be given of a gallium nitride-based semiconductor light-emitting device and a method of fabricating the same, referring to the accompanying drawings.

FIG. 2 is a sectional view of a gallium nitride-based semiconductor light-emitting device according to the present invention.

Referring to FIG. 2, the gallium nitride-based semiconductor light-emitting device according to the present invention includes a substrate 21, a first conductive gallium nitride-based semiconductor layer 22 formed on the substrate 21, an active layer 23 grown on the first conductive gallium nitride-based semiconductor layer 22 to have a Ga polarity, a polarity conversion layer 24, containing a MgN-based single crystal, formed on the active layer 23, and a second conductive gallium nitride-based semiconductor layer 25 grown on the polarity conversion layer 24 to have an N polarity.

In this regard, the polarity conversion layer 24, which serves to convert polarities of the GaN-based semiconductor layers positioned on upper and lower surfaces thereof so that the two polarities are opposite to each other, is made of a MgN-based material satisfying a compositional formula of (AlₓGa_{y}In_{z})Mg_{3-(x+y+z)}N₂ (0≦x,y,z≦1, 0<x+y+z<3), and may be grown according to a typical process of growing a light-emitting diode, that is, a molecular beam epitaxy (MBE) process or a metalorganic chemical vapor deposition (MOCVD) process.

Under typical growth conditions, a GaN thin film is grown to have the Ga polarity. However, the Ga polarity of the GaN thin film while growing may be converted into the N polarity by the MgN-based polarity conversion layer. Generally, a thin film with the Ga polarity has a smooth surface, and a thin film with the N polarity has a rough surface.

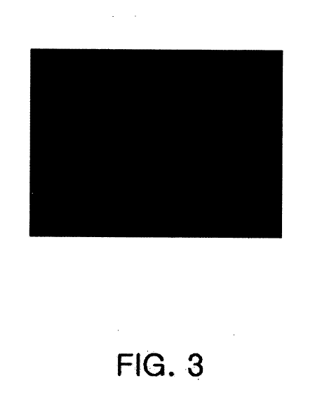

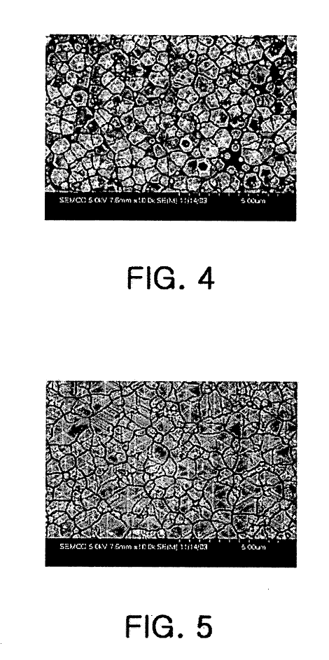

FIG. 3 is a SEM picture illustrating a surface of the thin film with the Ga polarity, and FIG. 4 is a SEM picture illustrating a surface of the thin film with the N polarity, in which the surface of the thin film with the Ga polarity is smooth but the surface of the thin film with the N polarity is rough.

Hence, the second conductive gallium nitride-based semiconductor layer 25 formed on the polarity conversion layer 24 has a rough surface regardless of a growth temperature. In other words, since the gallium nitride-based semiconductor layer has the rough surface even though it is grown at a high temperature of 1000° C., a deterioration of crystallinity and electric conductivity caused by a low temperature growth is avoided.

At this time, it is preferable that the polarity conversion layer is formed in a thickness of 500 Å or less so that light emitted from the active layer 23 is transmitted through the polarity conversion layer without a loss.

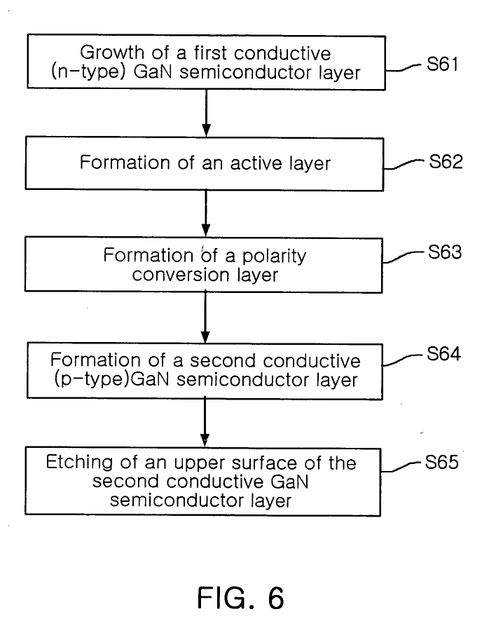

FIG. 6 is a flow chart illustrating the fabrication of the above gallium nitride-based semiconductor light-emitting device.

With reference to FIG. 6, in order to fabricate the gallium nitride-based semiconductor light-emitting device, the first conductive gallium nitride-based semiconductor layer 22 and active layer 23 are sequentially grown on the substrate 21 according to the typical MOCVD process (s61, s62).

In this respect, the first conductive gallium nitride-based semiconductor layer 22 and active layer 23 are grown under the typical growth conditions, and each have the Ga polarity and the smooth surface as shown in FIG. 3.

Subsequently, the MgN-based polarity conversion layer 24 is formed on the upper surface of the active layer 23 (s63).

The polarity conversion layer 24 is made of a material satisfying the compositional formula of (AlₓGa_{y}In_{z})Mg_{3-(x+y+z)}N₂ (0≦x,y,z≦1, 0<x+y+z<3), and formed according to the MBE or MOCVD processes. In this regard, the polarity conversion layer 24 is thinly formed in the thickness of 500 Å or less.

Successively, the second conductive gallium nitride-based semiconductor layer 25 is grown so as to have the N polarity by the polarity conversion layer 24 on the polarity conversion layer 24 (s64).

The second conductive gallium nitride-based semiconductor layer 25 thus grown has a rough surface as shown in FIG. 4.

Furthermore, the surface of the second conductive gallium nitride-based semiconductor layer 25 may be etched according to proper electrochemical wet etching or wet etching processes (s65), in such a case, a surface roughness of the second conductive gallium nitride-based semiconductor layer 25 is further increased. FIG. 5 is a SEM picture illustrating the properly etched surface of the second conductive gallium nitride-based semiconductor layer 25, in which the protrusions and recesses of the rough surface are larger than those of FIG. 4. At this time, an etching solution of the second conductive gallium nitride-based semiconductor layer 25 may be exemplified by any solution capable of etching a gallium-based semiconductor material, and may be selected from the group consisting of a molten potassium hydroxide (KOH) solution, a phosphoric acid solution, a sulfuric acid solution, and a mixed solution of phosphoric acid and sulfuric acid as well known in the art.

In the gallium nitride-based semiconductor light-emitting device fabricated through the above procedure, the second conductive gallium nitride-based semiconductor layer is formed in such a way that its surface is made rough to reduce an internal total reflectivity, thereby improving light extraction efficiency of light emitted from the active layer 23.

As apparent from the above description, the present invention is advantageous in that a second conductive gallium nitride-based semiconductor layer is grown in such a way that its surface is made rough by use of a polarity conversion layer regardless of a growth temperature, and thus, a desired surface roughness can be gained without a reduction of crystallinity and electric conductivity of the second conductive gallium nitride-based semiconductor layer, thereby reducing an internal total reflectivity, resulting in improved light extraction efficiency of a light-emitting device.

The present invention has been described in an illustrative manner, and it is to be understood that the terminology used is intended to be in the nature of description rather than of limitation. Many modifications and variations of the present invention are possible in light of the above teachings. Therefore, it is to be understood that within the scope of the appended claims, the invention may be practiced otherwise than as specifically described.

1. A gallium nitride-based semiconductor light-emitting device, comprising:
a substrate;
a first conductive gallium nitride-based semiconductor layer formed on the substrate;
an active layer grown on the first conductive gallium nitride-based semiconductor layer to have a Ga polarity;
a polarity conversion layer, containing a MgN-based single crystal, formed on the active layer; and
a second conductive gallium nitride-based semiconductor layer grown on the polarity conversion layer to have an N polarity.

2. The gallium nitride-based semiconductor light-emitting device as set forth in claim 1, wherein the polarity conversion layer is made of a material satisfying a compositional formula of (AlₓGa_{y}In_{z})Mg_{3-(x+y+z)}N₂, provided that 0≦x,y,z≦1 and 0<x+y+z<3.

3. The gallium nitride-based semiconductor light-emitting device as set forth in claim 1, wherein the polarity conversion layer is formed according to a molecular beam epitaxy (MBE) process or a metalorganic chemical vapor deposition (MOCVD) process.

4. The gallium nitride-based semiconductor light-emitting device as set forth in claim 1, wherein the polarity conversion layer is 500 Å or less in thickness.

5. A method of fabricating a gallium nitride-based semiconductor light-emitting device, comprising:
forming a first conductive gallium nitride-based semiconductor layer on a substrate;
growing an active layer with a multi quantum well structure on the first conductive gallium nitride-based semiconductor layer so as to have a Ga polarity;
forming a polarity conversion layer on the active layer; and
growing a second conductive gallium nitride-based semiconductor layer on the polarity conversion layer so as to have an N polarity.

6. The method as set forth in claim 5, wherein the polarity conversion layer is made of a material satisfying a compositional formula of (AlₓGa_{y}In_{z})Mg_{3-(x+y+z)}N₂, provided that 0≦x,y,z≦1 and 0<x+y+z<3.

7. The method as set forth in claim 5, wherein the polarity conversion layer is formed according to a molecular beam epitaxy (MBE) process or a metalorganic chemical vapor deposition (MOCVD) process.

8. The method as set forth in claim 5, wherein the polarity conversion layer is formed in a thickness of 500 Å or less.

9. The method as set forth in claim 5, further comprising etching an upper surface of the second conductive gallium nitride-based semiconductor layer according to a wet etching process.

10. The method as set forth in claim 9, wherein an etching solution is any one selected from the group consisting of a molten potassium hydroxide (KOH) solution, a phosphoric acid solution, a sulfuric acid solution, and a mixed solution of phosphoric acid and sulfuric acid.
